(19) United States
(12) Patent Application Publication
(10) Pub. No.: US 2007/0158181 A1
(43) Pub. Date: Jul. 12, 2007

(54) Method & apparatus for cathode sputtering with uniform process gas distribution

(75) Inventors: Chang Bok Yi, Fremont, CA (US); Tatsuru Tanaka, Campbell, CA (US); Thomas L. Greenberg, Berkeley, CA (US); Christopher C. Neill, San Jose, CA (US)

Correspondence Address: SEAGATE TECHNOLOGY LLC;c/o MCDERMOTT WILL & EMERY LLP, 600 13TH STREET, NW, WASHINGTON, DC, 20005-3096, US

(73) Assignee: SEAGATE TECHNOLOGY LLC

(21) Appl. No.: 11/330,200

(22) Filed: Jan. 12, 2006

(51) Int. Cl. C23C 14/00

(52) U.S. Cl. 204/192.12; 204/298.01

(57) ABSTRACT

A method of sputter depositing a substantially circumferentially uniform thin film on a surface of a circular, planar disk-shaped substrate, comprising steps of: (a) providing a cathode sputtering apparatus including: a vacuum chamber; a cathode sputtering source comprising a circularly-shaped sputtering target assembly with a first target having a planar sputtering surface and a circumferentially extending edge; and a circular disk-shaped substrate with a planar surface positioned in spaced opposition to the sputtering surface; and (b) sputter depositing the thin film on the substrate surface while providing the chamber with a substantially uniform flow of at least one process gas around the entirety of the circumferentially extending edge of the sputtering target assembly.

### FIELD OF THE INVENTION

The present invention relates to a method and apparatus for injection of gas(es) into a vacuum chamber of a sputtering apparatus for obtaining highly uniform composition sputter deposition of thin films over substantially the entire surface area(s) of a circularly-shaped substrate. The invention has particular utility in the manufacture of disk-shaped magnetic and magneto-optical data/information recording, storage, and retrieval media, wherein at least one constituent layer of the media is formed by a reactive sputter deposition process.

### BACKGROUND OF THE INVENTION

Magnetic and MO recording media are widely employed in various applications, particularly in the computer industry for data/information recording, storage, and retrieval purposes. A magnetic medium in, e.g., disk form, such as utilized in computer-related applications, comprises a non-magnetic substrate, for example, of glass, ceramic, glass-ceramic composite, polymer, metal or metal alloy, typically an aluminum (Al)-based alloy such as aluminum-magnesium (Al—Mg), having at least one major surface on which a layer stack comprising a plurality of thin film layers constituting the medium are sequentially deposited. In the case of longitudinal type magnetic recording media, such layers may include, in sequence from the substrate deposition surface, a plating layer, e.g., of amorphous nickel-phosphorus (Ni—P), a polycrystalline underlayer, typically of chromium (Cr) or a Cr-based alloy such as chromium-vanadium (Cr—V), a longitudinally oriented magnetic layer, e.g., of a cobalt (Co)-based alloy, and a protective overcoat layer, typically of a carbon (C)-based material, such as diamond-like carbon (DLC), having good mechanical (i.e., tribological) and corrosion resistance properties. Perpendicular type magnetic recording media typically comprise, in sequence from the surface of a non-magnetic substrate, an underlayer of a magnetically soft material, at least one non-magnetic interlayer or intermediate layer, a vertically (i.e., perpendicularly) oriented recording layer of a magnetically hard material, and a protective overcoat layer.

A similar situation exists with magneto-optical (MO) media, wherein a layer stack is formed which comprises a reflective layer, typically of a metal or metal alloy, one or more rare-earth thermo-magnetic (RE-TM) alloy layers, one or more dielectric layers, and a protective overcoat layer, for functioning as reflective, transparent, writing, writing assist, and read-out layers, etc.

According to conventional manufacturing technology, a majority (if not all) of the above-described layers constituting stacked multi-layer longitudinal and perpendicular magnetic media, as well as MO recording media, are deposited by means of cathode sputtering processing. For example, the magnetic recording layers are typically fabricated by sputter depositing a Co-based alloy film, wherein the alloying elements are selected to promote desired magnetic and microstructural properties. In the case of longitudinal-type magnetic disk recording media, metallic and metalloidal elements, such as, for example, Cr, Pt, Ta, B, and combinations thereof, have been found to be effective. Similar alloying elements have been found to be useful in the case of perpendicular-type magnetic disk recording media, and in addition, reactive sputter deposition of the Co-based alloys in an oxygen (O₂)-containing atmosphere has been found to be especially effective in controlling (i.e., limiting) exchange coupling between adjacent magnetic grains.

In a typical reactive sputtering process utilized for formation of perpendicular-type magnetic recording media, O₂ gas is mixed with an inert sputtering gas, e.g., Ar, and is consumed by the depositing Co-based alloy magnetic film. Due to the high reactivity of O₂ with metals, and since only partial oxidation of the depositing Co-based alloy magnetic film is desired, the degree of oxidation as a function of the location or position on the substrate (i.e., disk) surface tends to exhibit wide variation depending upon the process conditions, including, inter alia, O₂ injection geometry, gas pumping (i.e., evacuation) geometry, gas flow rate, and film deposition rate.

FIG. 1 is a simplified, schematic, perspective view of a portion of an example of a one disk at-a-time sputtering apparatus 10 which may be utilized for sputter deposition of thin films as part of the manufacturing process of disk-shaped magnetic or MO recording media. As illustrated, apparatus 10 comprises: a vacuum chamber 1 equipped with an opening 2 at the bottom end thereof for connection to a pumping means for evacuating the interior of the chamber; at least one, preferably a pair of facing, circularly-shaped sputtering targets or sources 3A and 3B of conventional type, e.g., a pair of magnetron sputtering guns; a workpiece support or holder (not shown in the figure for illustrative clarity) for positioning a substrate/workpiece in the space between the pair of facing sputtering sources, illustratively a circular disk-shaped substrate 4 for a magnetic or MO recording medium, adapted for receipt of sputtered particle flux on the opposing surfaces thereof; and a gas injector 5 having a gas inlet portion 6 extending outside of chamber 1 for connection to a source of a process gas, and a gas outlet portion 7 within the chamber, for injecting the process gas, e.g., an inert gas such as Ar, Kr, etc., or a reactive gas such as N₂, O₂, etc., in the space between the facing pair of sputtering sources 3A and 3B. Illustratively, the gas injector 5 is “wishbone”-shaped, and comprises a linearly elongated, tubular inlet portion 6 having a first, gas inlet end, and a second end 7, with a pair of arcuately-shaped, tubular gas outlet portions 8A and 8B extending from the second end, comprising a plurality of spaced-apart, narrow diameter gas outlet orifices 9.

It has been determined that one-disk-at-a-time sputtering apparatus for the hard disk manufacturing industry, such as described above, employ gas injection systems with design criteria, e.g., geometries, which are poorly suited to the high film uniformity requirements of the hard disk industry, particularly with respect to the special problems presented by reactive sputtering in atmospheres containing O₂ for formation of granular magnetic recording layers. For example, as the oxide content of granular magnetic films increases, the exchange coupling between adjacent magnetic grains decreases, the hysteresis slope decreases, and S* (a measure of the oxygen content) decreases.

More specifically, in the case of “top-center” O₂/Ar injection, S* is highest at the bottom of the disks (i.e., at 180°), indicating that the bottom of the disks is oxide-poor, relative to the disk top and sides (i.e., 0, 90, and 270°). By contrast, in the case of “bottom-side” O₂/Ar injection, S* is lowest, i.e., the oxide content is highest, at the 90° position, corresponding to the region of the disk directly above the O₂/Ar injection port. However, variation, e.g., asymmetry, of the oxide content of the deposited magnetic films, as inferred from the values of the parameter S*, can be correlated with the O₂/Ar injection geometry of the sputtering apparatus. In general, the oxide content is highest in the region of the disk surface which is closest to the point of O₂/Ar injection. For the same sputtering chamber and pumping (evacuation) hardware, disks can be manufactured in which the magnetic recording layer is oxide rich at the top, bottom, or side(s), depending upon the geometry of the O₂/Ar injection system, suggesting that the variation in oxide content of the magnetic recording layer (as reflected in the value of S*) can be reduced by proper design of the injection geometry/system.

FIG. 2 is a simplified, schematic, view of a portion (i.e., a center sectional view) of another example of a one at-a-time sputtering apparatus 20 which may be utilized for sputter deposition of thin films as part of the manufacturing process of disk-shaped magnetic and MO recording media. As illustrated, sputtering apparatus 20 comprises a vacuum chamber 11 equipped with a vertically movable workpiece/substrate mount or holder 12 for positioning a circular disk-shaped media substrate 4 in spaced opposition to a circularly-shaped sputtering target or source 13 of conventional type, e.g., a magnetron sputtering gun, for receipt of sputtered particle flux on a first, facing surface thereof. Chamber 11 typically includes another, similarly configured, circularly-shaped sputtering target or source (not shown in FIG. 2) positioned in spaced opposition to a second, opposing surface of substrate 4 for sputter deposition thereon. As shown in the figure, chamber 11 is provided with a pair of channels 13A and 13B which extend through the chamber base 12 at opposite ends thereof for supplying process gas(es) to the interior space of the chamber. Each of the channels 13A and 13B includes a respective branch portion 14A and 14B terminating at gas injection ports or orifices 15A and 15B formed in respective interior wall portions 16A and 16B of chamber 11 for supplying process gas to the lower portion of the chamber, as well as respective elongated, upwardly extending branches 17A and 17B respectively terminating in side gas injection ports or orifices 18A and 18B and top gas injection ports or orifices 19A and 19B for supplying process gas(es) to the side and upper portions of chamber 11. The process gas(es) supplied to the interior of chamber 11 is (are) evacuated via outlets at the lower portion of the chamber (not shown in the figure for illustrative simplicity).

According to this arrangement, control of the process gas pressure distribution within chamber 11 is possible only by closing or opening selected ones of gas injection ports or orifices 13A, 13B, 18A, 18B, 19A, and 19B. For example, if the bottom and side gas injection ports or orifices 13A, 13B, 18A, and 18B are closed (e.g., plugged), the process gas is injected only via the top gas injection ports or orifices 19A and 19B. Disadvantageously, however, irrespective of which gas injection port or orifice, or combination of gas injection ports or orifices, is utilized, a gas pressure gradient will exist from the top to the bottom of chamber 11, and in addition, a difference in gas pressure across the sides of substrate 4 will be established if the pumping path for gas evacuation is not symmetrical.

The top-to-bottom process gas pressure gradient which is established as described above typically has an adverse affect on the properties of the sputter deposited thin films. More specifically, the top-to-bottom gas pressure gradient results in circumferentially non-uniform magnetic properties of the various magnetic layers, including soft underlayers and longitudinal and perpendicular recording layers. The effect of circumferential non-uniformity of the sputter deposition process is particularly observed when the films are formed by a reactive sputtering process, as in the formation of granular magnetic films.

In view of the foregoing, there exists a clear need for improved means and methodology for depositing thin films by sputtering techniques (e.g., reactive sputtering) and at deposition rates consistent with the throughput requirements of automated manufacturing processing, which have a specified, typically minimal, variation over the substrate surface. More specifically, there exists a need for improved means and methodology for overcoming the above-described drawbacks and disadvantages associated with sputter deposition processing for the manufacture of hard disk magnetic and MO recording media, notably reactive sputtering involving oxide content variation over the disk surface which exceeds specified manufacturing tolerances.

The present invention addresses and solves the problems, disadvantages, and drawbacks described supra in connection with conventional means and methodology for performing sputter deposition of thin films, particularly reactive sputtering of oxide-containing perpendicular magnetic recording layers, while maintaining full compatibility with all aspects of conventional automated manufacturing technology for hard disk magnetic and MO recording media. Further, the means and methodology afforded by the present invention enjoy diverse utility in the manufacture of all manner of devices and products requiring formation of high compositional uniformity thin films by means of reactive sputtering processing.

### DISCLOSURE OF THE INVENTION

An advantage of the present invention is an improved sputtering apparatus.

Another advantage of the present invention is an improved apparatus for sputter depositing substantially circumferentially uniform thin films on circular-shaped substrates.

Yet another advantage of the present invention is an improved method for sputter depositing substantially circumferentially uniform thin films on circular-shaped substrates.

Additional advantages and other features of the present invention will be set forth in the description which follows and in part will become apparent to those having ordinary skill in the art upon examination of the following or may be learned from the practice of the present invention. The advantages of the present invention may be realized and obtained as particularly pointed out in the appended claims.

According to an aspect of the present invention, the foregoing and other advantages are obtained in part by a cathode sputtering apparatus, comprising:

a) a vacuum chamber;

b) a first cathode sputtering source in the chamber, comprising a first circularly-shaped sputtering target assembly with a first target having a planar sputtering surface and a circumferentially extending edge;

c) a workpiece holder in the chamber, adapted for positioning a first, planar surface of a circular disk-shaped substrate in spaced opposition to the sputtering surface of the first target; and

d) a first gas supply system for providing the chamber with at least one process gas, adapted for supplying a uniform flow of the at least one process gas around the entirety of the circumferentially extending edge of the first sputtering target assembly, whereby substantially circumferentially uniform thin films are sputter-deposited on the first surface of the substrate.

According to preferred embodiments of the present invention, the first gas supply system comprises a gas inlet conduit for introducing the at least one process gas into a space formed between a rear side of the first sputtering target assembly and a mounting plate for mounting the first sputtering source to a wall of the vacuum chamber; and further comprises a gap formed between the circumferentially extending edge of the first sputtering target assembly and a cathode dark shield surrounding the edge, the space and the gap being in fluid communication.

Preferably, the first target assembly comprises a magnet assembly behind the first target, with a cooling plate between the magnet assembly and the first target; and the workpiece holder is vertically movable between first and second positions for introducing and withdrawing the substrate from the chamber.

In accordance with further preferred embodiments of the present invention, the apparatus further comprises:

(e) a second cathode sputtering source in the chamber, comprising a second circularly-shaped sputtering target assembly with a second target having a planar sputtering surface and a circumferentially extending edge, the workpiece holder adapted for positioning a second, planar surface of the circular disk-shaped substrate in spaced opposition to the second sputtering surface; and

(f) a second gas supply system for providing the chamber with at least one process gas, adapted for supplying a uniform flow of the at least one process gas around the entirety of the circumferentially extending edge of the second sputtering target assembly, whereby substantially circumferentially uniform thin films are sputter-deposited on the second surface of the substrate.

Preferably, the second gas supply system comprises a gas inlet conduit for introducing the at least one process gas into a space formed between a rear side of the second sputtering target assembly and a mounting plate for mounting the second sputtering source to a wall of the vacuum chamber, and further comprises a gap formed between the circumferentially extending edge of the second sputtering target assembly and a cathode dark shield surrounding the edge, the space and the gap being in fluid communication.

According to preferred embodiments of the present invention, the second target assembly comprises a magnet assembly behind the second target, and a cooling plate between the magnet assembly and the second target.

Another aspect of the present invention is a method of sputter depositing a substantially circumferentially uniform thin film on at least a first surface of a circular, planar disk-shaped substrate, comprising steps of:

(a) providing a cathode sputtering apparatus including:
(i) a vacuum chamber;
(ii) at least a first cathode sputtering source in the chamber, comprising a first circularly-shaped sputtering target assembly with a first target having a planar sputtering surface and a circumferentially extending edge;
(iii) a circular disk-shaped substrate with a first planar surface positioned in spaced opposition to the sputtering surface of the first target; and

(b) sputter depositing the thin film on the first surface of the substrate while providing the chamber with a substantially uniform flow of at least one process gas around the entirety of the circumferentially extending edge of the first sputtering target assembly.

Preferably, step (b) comprises introducing the at least one process gas into the chamber via a space formed between a rear side of the first sputtering target assembly and a mounting plate for mounting the first sputtering source to a wall of the vacuum chamber, and further comprises flowing the at least one process gas from the space to a gap in fluid communication therewith and formed between the circumferentially extending edge of the first sputtering target assembly and a cathode dark shield surrounding the edge.

In accordance with preferred embodiments of the present invention, step (a) comprises providing a cathode sputtering apparatus including a second cathode sputtering source in the chamber, comprising a second circularly-shaped sputtering target assembly with a second target having a planar sputtering surface and a circumferentially extending edge, and the circular disk-shaped substrate has a second planar surface positioned in spaced opposition to the sputtering surface of the second target; and step (b) comprises sputter depositing the thin film on the second surface of the substrate while providing the chamber with a substantially uniform flow of at least one process gas around the entirety of the circumferentially extending edge of the second sputtering target assembly.

Preferably, step (b) comprises introducing the at least one process gas into the chamber via a space formed between a rear side of the second sputtering target assembly and a mounting plate for mounting the second sputtering source to a wall of the vacuum chamber, and further comprises flowing the at least one process gas from the space to a gap in fluid communication therewith and formed between the circumferentially extending edge of the second sputtering target assembly and a cathode dark shield surrounding the edge.

Preferred embodiments of the present invention include those wherein step (a) comprises providing a non-magnetic substrate for a magnetic or MO recording medium; and step (b) comprises sputter depositing a magnetic thin film on the substrate by a process including supplying the chamber with a reactive gas.

Additional advantages and aspects of the present invention will become readily apparent to those skilled in the art from the following detailed description, wherein embodiments of the present invention are shown and described, simply by way of illustration of the best mode contemplated for practicing the present invention. As will be described, the present invention is capable of other and different embodiments, and its several details are susceptible of modification in various obvious respects, all without departing from the spirit of the present invention. Accordingly, the drawings and description are to be regarded as illustrative in nature, and not as limitative.

### BRIEF DESCRIPTION OF THE DRAWINGS

The following detailed description of the embodiments of the present invention can best be understood when read in conjunction with the following drawings, in which the same reference numerals are employed throughout for designating like features and wherein the various features are not necessarily drawn to scale but rather are drawn as to best illustrate the pertinent features, wherein:

FIG. 1 is a simplified, schematic, perspective view of a portion of one example of a one disk at-a-time sputtering apparatus which may be utilized for sputter deposition of thin films as part of the manufacturing process of disk-shaped magnetic or MO recording media;

FIG. 2 is a simplified, schematic, view (i.e., a center sectional view) of a portion of another example of a one at-a-time sputtering apparatus which may be utilized for sputter deposition of thin films as part of the manufacturing process of disk-shaped magnetic and MO recording media;

FIG. 3 is a simplified, schematic, cross-sectional view of an illustrative, but non-limitative example, of an embodiment of one at-a-time sputtering apparatus according to the present invention, which apparatus is preferably utilized for sputter deposition of thin films, including reactive sputter deposition of magnetic thin films, as part of the manufacturing process of disk-shaped magnetic and MO recording media;

FIG. 4 is a graph for illustrating the circumferential uniformity of magnetic thin films sputter deposited on circular disk-shaped substrates utilizing the apparatus of FIG. 2; and

FIG. 5 is a graph for illustrating the circumferential uniformity of magnetic thin films sputter deposited on circular disk-shaped substrates utilizing the apparatus of FIG. 3 according to the present invention.

### DESCRIPTION OF THE INVENTION

As previously indicated, the present invention addresses and solves problems, disadvantages, and drawbacks described supra, i.e., poor circumferential uniformity of film composition and magnetic performance properties, such as are encountered when thin films are formed by sputter deposition techniques and methodologies, particularly reactive sputtering of oxide-containing perpendicular magnetic recording layers, while maintaining full compatibility with all aspects of conventional automated manufacturing technology for hard disk magnetic and MO recording media. Advantageously, the means and methodology afforded by the present invention enjoy diverse utility in the manufacture of all manner of devices and products requiring formation of high compositional uniformity thin films by means of sputter deposition.

The present invention is based upon recognition that substantial improvement in circumferential uniformity of sputter-deposited thin films, including reactively sputtered thin films such as granular magnetic recording layers, can be obtained with one-at-time sputtering apparatus including at least one opposing circular sputtering target assembly—circular substrate arrangement, by introducing the sputter process gas(es) to the deposition chamber via the backside of the at least one circularly-shaped sputtering source, such that a uniform flow of the process gas(es) occurs around the entire circumferentially extending edge of the at least one sputtering target assembly.

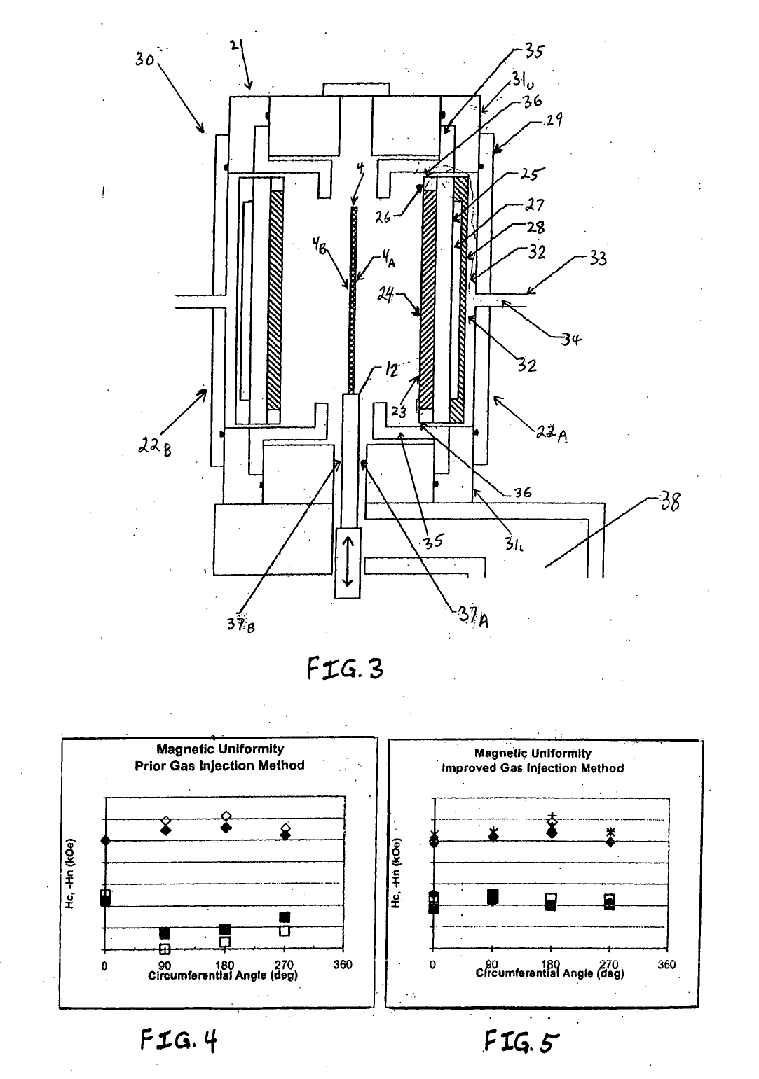

Referring to FIG. 3, shown therein is a simplified, schematic, cross-sectional view of an illustrative, but non-limitative, example of an embodiment of one at-a-time sputtering apparatus 30 according to the present invention, which apparatus is preferably utilized for sputter deposition of thin films, including reactive sputter deposition of magnetic thin films, as part of a manufacturing process of disk-shaped magnetic and MO recording media.

As illustrated, apparatus 30 comprises a vacuum chamber 21 including therein substantially identically configured first and second circularly-shaped sputtering sources 22_{A} and 22_{B} positioned at opposite sides of chamber 21, with a circular disk-shaped substrate or workpiece 4 centrally positioned between and in opposition to the sputtering surfaces of the first and second circularly-shaped sputtering sources 22_{A} and 22_{B} for receipt of sputtered particle flux on respective surfaces 4_{A} and 4_{B}. Inasmuch as sputtering sources 22_{A} and 22_{B} are substantially identically structured, the following detailed description is limited, for brevity, to the structure of first sputtering source 22_{A}.

As shown, first circularly-shaped sputtering source 22_{A} comprises a target assembly including circular disk-shaped target 23 with planar sputtering surface 24 in spaced opposition to substrate surface 4_{A}. The back surface of target 23 is mounted to a cooling plate 25 by means of an annular target clamp ring 26 extending around the circumference of target 23. A magnet assembly 27, e.g., a magnetron assembly, is mounted to the back surface of cooling plate 25 via magnet clamp plate 28, and the target assembly is in turn mounted to upper and lower flange portions 31_{U} and 31_{L} of chamber 21 in an electrically insulated and gas-tight manner via mounting plate 29, such that a space 32 is formed between the back surface of the magnet clamp plate 28 and the front surface of mounting plate 29. A process gas supply tube 33 extends through mounting plate 29 at a central portion thereof for providing a gas flow passage 34 in fluid communication with space 32. An annular flange-shaped member forming a cathode dark space shield 35 extends around the circumference of target clamp ring 26 with a narrow, annular-shaped gap 36 therebetween, gap 36 being in fluid communication with space 32.

Still referring to FIG. 3, reference numeral 12 indicates a vertically movable substrate/workpiece mount/support for introducing and withdrawing disk-shaped substrate/workpiece 4 to/from the interior of vacuum chamber 21; and reference numerals 37_{A} and 37_{B} indicate passages for gas withdrawal and pumping via vacuum port 38.

During operation of apparatus 30 for thin film formation on at least first surface 4_{A} of substrate 4 via deposition from first sputter source 22_{A}, at least one process gas, e.g., at least one of Ar, Kr, N₂, O₂, etc., is supplied to gas inlet tube 33, and travels to the interior of chamber 21 via gas flow passage 34, space 32, and annular gap 36. Inasmuch as annular gap 36 extends completely around the circumference of the target clamp ring 26 of sputter source 22_{A}, a substantially circumferentially uniform flow and pressure distribution of process gas is established around the circumferences of target 24 and substrate surface 4_{A}, resulting in deposition thereon of circumferentially uniform thin films. A similar gas flow/pressure distribution is obtained with second sputter source 22_{B} for affording circumferentially uniform deposition of a desired thin film layer on the second surface 4_{B} of substrate/workpiece 4.

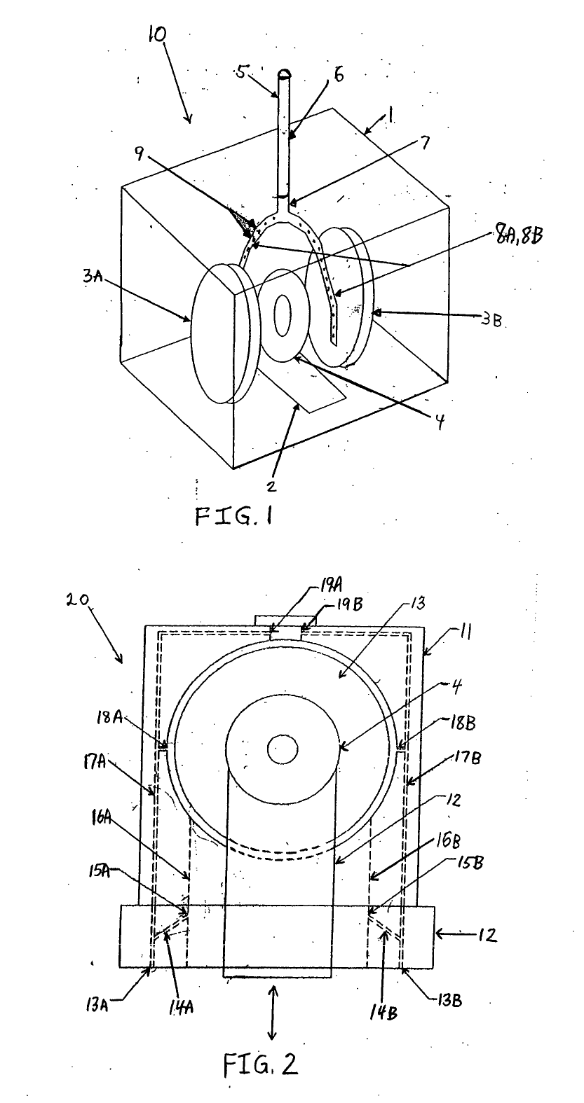

The utility of the present invention is demonstrated with reference to FIG. 4, which is a graph for illustrating the circumferential uniformity of magnetic thin films sputter deposited on circular disk-shaped substrates utilizing the apparatus 20 of FIG. 2, and with reference to FIG. 5, which is a graph for illustrating the circumferential uniformity of magnetic thin films sputter deposited on circular disk-shaped substrates utilizing the apparatus 30 of FIG. 3 according to the present invention. As is clearly evident from a comparison of the graphs of FIGS. 4 and 5, circumferential uniformity of the magnetic properties of magnetic thin films sputter deposited on circular disk-shaped substrates is substantially improved by means of the back-side process gas injection methodology/apparatus according to the instant invention.

The inventive methodology and apparatus enjoy particular utility in the formation of granular magnetic recording layers utilizing reactive sputtering techniques wherein a reactive gas, e.g., oxygen, is introduced to the sputter gas atmosphere for formation of films having magnetic grains with improved inter-grain isolation reducing inter-grain magnetic coupling and enhancing the magnetic properties thereof.

The present invention thus provides a number of advantages over conventional apparatus and methodology for sputtering, e.g., reactive sputtering, including improved compositional uniformity over 360° of a substrate surface, such as a magnetic disk substrate. Further, utilization of the inventive apparatus and methodology as part of conventional manufacturing apparatus and methodology for hard disk recording media can be readily implemented, in view of the full compatibility of the invention with all other aspects of automated media manufacture. Finally, the inventive apparatus and methodology are broadly applicable to reactive sputtering processing utilized for the manufacture of a variety of different products, e.g., coated architectural glass and multi-layer optical coatings.

In the previous description, numerous specific details are set forth, such as specific materials, structures, processes, etc., in order to provide a better understanding of the present invention. However, the present invention can be practiced without resorting to the details specifically set forth. In other instances, well-known processing materials and techniques have not been described in detail, in order not to unnecessarily obscure the present invention.

Only the preferred embodiments of the present invention and but a few examples of its versatility are shown and described in the present invention. It is to be understood that the present invention is capable of use in various other embodiments and is susceptible of changes and/or modifications within the scope of the inventive concept as expressed herein.

What is claimed is:

1. A cathode sputtering apparatus, comprising:
(a) a vacuum chamber;
(b) a first cathode sputtering source in said chamber, comprising a first circularly-shaped sputtering target assembly with a first target having a planar sputtering surface and a circumferentially extending edge;
(c) a workpiece holder in said chamber, adapted for positioning a first, planar surface of a circular disk-shaped substrate in spaced opposition to said sputtering surface of said first target; and
(d) a first gas supply system for providing said chamber with at least one process gas, adapted for supplying a uniform flow of said at least one process gas around the entirety of said circumferentially extending edge of said first sputtering target assembly, whereby substantially circumferentially uniform thin films are sputter-deposited on said first surface of said substrate.

2. The apparatus as in claim 1, wherein:
said first gas supply system comprises a gas inlet conduit for introducing said at least one process gas into a space formed between a rear side of said first sputtering target assembly and a mounting plate for mounting said first sputtering source to a wall of said vacuum chamber.

3. The apparatus as in claim 2, wherein:
said first gas supply system further comprises a gap formed between said circumferentially extending edge of said first sputtering target assembly and a cathode dark shield surrounding said edge, said space and said gap being in fluid communication.

4. The apparatus as in claim 1, wherein:
said first target assembly comprises a magnet assembly behind said first target.

5. The apparatus as in claim 4, further comprising:
a cooling plate between said magnet assembly and said first target.

6. The apparatus as in claim 1, wherein:
said workpiece holder is vertically movable between first and second positions for introducing and withdrawing said substrate from said chamber.

7. The apparatus as in claim 1, further comprising:
(e) a second cathode sputtering source in said chamber, comprising a second circularly-shaped sputtering target assembly with a second target having a planar sputtering surface and a circumferentially extending edge, said workpiece holder adapted for positioning a second, planar surface of said circular disk-shaped substrate in spaced opposition to said second sputtering surface; and
(f) a second gas supply system for providing said chamber with at least one process gas, adapted for supplying a uniform flow of said at least one process gas around the entirety of said circumferentially extending edge of said second sputtering target assembly, whereby substantially circumferentially uniform thin films are sputter-deposited on said second surface of said substrate.

8. The apparatus as in claim 7, wherein:
said second gas supply system comprises a gas inlet conduit for introducing said at least one process gas into a space formed between a rear side of said second sputtering target assembly and a mounting plate for mounting said second sputtering source to a wall of said vacuum chamber.

9. The apparatus as in claim 8, wherein:
said second gas supply system further comprises a gap formed between said circumferentially extending edge of said second sputtering target assembly and a cathode dark shield surrounding said edge, said space and said gap being in fluid communication.

10. The apparatus as in claim 7, wherein:
said second target assembly comprises a magnet assembly behind said second target.

11. The apparatus as in claim 10, further comprising:
a cooling plate between said magnet assembly and said second target.

12. A method of sputter depositing a substantially circumferentially uniform thin film on at least a first surface of a circular, planar disk-shaped substrate, comprising steps of:
(a) providing a cathode sputtering apparatus including:
(i) a vacuum chamber;
(ii) at least a first cathode sputtering source in said chamber, comprising a first circularly-shaped sputtering target assembly with a first target having a planar sputtering surface and a circumferentially extending edge;
(iii) a circular disk-shaped substrate with a first planar surface positioned in spaced opposition to said sputtering surface of said first target; and
(b) sputter depositing said thin film on said first surface of said substrate while providing said chamber with a substantially uniform flow of at least one process gas around the entirety of said circumferentially extending edge of said first sputtering target assembly.

13. The method according to claim 12, wherein:
step (b) comprises introducing said at least one process gas into said chamber via a space formed between a rear side of said first sputtering target assembly and a mounting plate for mounting said first sputtering source to a wall of said vacuum chamber.

14. The method according to claim 13, wherein:
step (b) further comprises flowing said at least one process gas from said space to a gap in fluid communication therewith and formed between said circumferentially extending edge of said first sputtering target assembly and a cathode dark shield surrounding said edge.

15. The method according to claim 12, wherein:
step (a) comprises providing a cathode sputtering apparatus including a second cathode sputtering source in said chamber, comprising a second circularly-shaped sputtering target assembly with a second target having a planar sputtering surface and a circumferentially extending edge; and said circular disk-shaped substrate has a second planar surface positioned in spaced opposition to said sputtering surface of said second target; and
step (b) comprises sputter depositing said thin film on said second surface of said substrate while providing said chamber with a substantially uniform flow of at least one process gas around the entirety of said circumferentially extending edge of said second sputtering target assembly.

16. The method according to claim 15, wherein:
step (b) comprises introducing said at least one process gas into said chamber via a space formed between a rear side of said second sputtering target assembly and a mounting plate for mounting said second sputtering source to a wall of said vacuum chamber.

17. The method according to claim 16, wherein:
step (b) further comprises flowing said at least one process gas from said space to a gap in fluid communication therewith and formed between said circumferentially extending edge of said second sputtering target assembly and a cathode dark shield surrounding said edge.

18. The method according to claim 12, wherein:
step (a) comprises providing a non-magnetic substrate for a magnetic or MO recording medium.

19. The method according to claim 18, wherein:
step (b) comprises sputter depositing a magnetic thin film on said substrate surface.

20. The method according to claim 19, wherein:
step (b) comprises supplying said chamber with a reactive gas.
